(19) United States
(12) Patent Application Publication
(10) Pub. No.: US 2006/0133140 A1
(43) Pub. Date: Jun. 22, 2006

(54) RFID tags storing component configuration data in non-volatile memory and methods

(76) Inventors: Vadim Gutnik, Irvine, CA (US); John D. Hyde, Corvallis, OR (US); David D. Dressler, Shoreline, WA (US); Alberto Pesavento, Seattle, WA (US); Ronald A. Oliver, Seattle, WA (US); Scott Anthony Cooper, Seattle, WA (US); Kurt Eugene Sundstrom, Woodinville, WA (US)

Correspondence Address: MERCHANT & GOULD PC, P.O. BOX 2903, MINNEAPOLIS, MN, 55402-0903, US

(21) Appl. No.: 11/015,293

(22) Filed: Dec. 17, 2004

(51) Int. Cl. G11C 11/34; G11C 14/00

(52) U.S. Cl. 365/185.08

(57) ABSTRACT

An RFID tag has a Non Volatile Memory (NVM) array that can store data in a way that survives loss of power. The data is configuration data that controls the operation of an operational component of the tag. A performance of the operational component is thus adjusted according to the configuration data, and the adjustment is retained.

### RELATIONSHIP TO OTHER PATENT APPLICATIONS

This application may be found to be related to another application by inventors Vadim Gutnik, John Hyde, David D. Dressler, Alberto Pesavento, Ronald A. Oliver, Scott Cooper and Kurt Sundstrom, titled “RFID TAGS WITH ELECTRONIC FUSES FOR STORING COMPONENT CONFIGURATION DATA”, filed with the USPTO on the same day as the present application, and due to be assigned to the same assignee.

This application incorporates by reference U.S. patent application titled “REWRITEABLE ELECTRONIC FUSES”, filed with the USPTO on 2004-03-30, and having Ser. No. 10/813,907 [Attorney Docket No. IMPJ-0027A].

This application incorporates by reference U.S. patent application titled “REWRITEABLE ELECTRONIC FUSES”, filed with the USPTO on 2004-03-30, and having Ser. No. 10/814,866 [Attorney Docket No. IMPJ-0027B].

This application incorporates by reference U.S. patent application titled “REWRITEABLE ELECTRONIC FUSES”, filed with the USPTO on 2004-03-30, and having Ser. No. 10/814,868 [Attorney Docket No. IMPJ-0027C].

### 1. FIELD OF THE INVENTION

The present invention is related to the field of Radio Frequency IDentification (RFID) systems, and more specifically to RFID tags with a component whose operation depends on configuration data stored in an on-board memory, and methods.

### 2. BACKGROUND

Radio Frequency IDentification (RFID) systems typically include RFID tags and RFID readers, which are also known as RFID reader/writers. RFID systems can be used in many ways for locating and identifying objects to which they are attached. RFID systems are particularly useful in product-related and service-related industries for tracking large numbers of objects being processed, inventoried, or handled. In such cases, an RFID tag is usually attached to an individual item, or to its package.

In principle, RFID techniques entail using an RFID reader to interrogate one or more RFID tags. Interrogation is performed by the reader transmitting a Radio Frequency (RF) wave. A tag that senses the interrogating RF wave responds by transmitting back another RF wave. The tag generates the transmitted back RF wave either originally, or by reflecting back a portion of the interrogating RF wave, a process known as backscatter. Backscatter may take place in a number of ways.

The reflected back RF wave may further encode data stored internally in the tag, such as a number. The response, and the data if available, is decoded by the reader, which thereby identifies, counts, or otherwise interacts with the associated item. The data can denote a serial number, a price, a date, a destination, other attribute(s), any combination of attributes, and so on.

An RFID tag typically includes an antenna system, a power management section, a radio section, and frequently a logical section, a memory, or both. In earlier RFID tags, the power management section included a power storage device, such as a battery. RFID tags with a power storage device are known as active tags. Advances in semiconductor technology have miniaturized the electronics so much that an RFID tag can be powered by the RF signal it receives enough to be operated. Such RFID tags do not include a power storage device, and are called passive tags.

### BRIEF SUMMARY

The invention improves over the prior art.

Briefly, an RFID tag has a Non Volatile Memory (NVM) array that can store data in a way that survives loss of power. The data includes configuration data that controls the operation of an operational component of the tag. A performance of the operational component can thus be adjusted by adjusting the configuration data, and the adjustment is retained.

These and other features and advantages will be better understood from the specification, which includes the following Detailed Description and accompanying drawings.

### BRIEF DESCRIPTION OF THE DRAWINGS

The following Detailed Description proceeds with reference to the accompanying Drawings, in which:

FIG. 1 is a block diagram of an RFID system.

FIG. 2 is a diagram showing components of a passive RFID tag, such as the tag shown in FIG. 1.

FIG. 3 is a conceptual diagram for explaining a frequent mode of communication between the components of the RFID system of FIG. 1 during normal operation in the field.

FIG. 4A is a block diagram of salient components of an RFID tag circuit according to embodiments of the invention, and further showing an embodiment where stored configuration data is input in an operational component responsive to a command.

FIG. 4B is the block diagram of FIG. 4A, and further showing an embodiment where stored configuration data is input in an operational component directly.

FIG. 4C is the block diagram of FIG. 4A, and further showing another embodiment where stored configuration data is input in an operational component indirectly.

FIG. 5 is a perspective diagram of a wafer being tested by a probe.

FIG. 6A is a block diagram of salient components of an RFID tag circuit according to another embodiment of the invention, using a controller to program configuration data.

FIG. 6B is the block diagram of FIG. 6A, and further showing another embodiment of how stored configuration data is input in an operational component.

FIG. 6C is the block diagram of FIG. 6A, and further showing an embodiment of how the controller determines what configuration data to store.

FIG. 6D is the block diagram of FIG. 6A, and further showing another embodiment of how the controller determines what configuration data to store.

FIG. 7A is a block diagram of a first possible embodiment of an operational component shown in FIG. 4A, FIG. 5, and FIG. 6A.

FIG. 7B is a block diagram of additional possible embodiments of an operational component shown in FIG. 4A, FIG. 5, and FIG. 6A.

FIG. 7C is a block diagram of further possible embodiments of an operational component shown in FIG. 4A, FIG. 5, and FIG. 6A.

FIG. 7D is a block diagram of additional possible embodiments of an operational component shown in FIG. 4A, FIG. 5, and FIG. 6A.

FIG. 7E is a block diagram of one more possible embodiment of an operational component shown in FIG. 4A, FIG. 5, and FIG. 6A.

FIG. 7F is a block diagram of another possible embodiment of an operational component shown in FIG. 4A, FIG. 5, and FIG. 6A.

FIG. 7G is a block diagram of one more possible embodiment of an operational component shown in FIG. 4A, FIG. 5, and FIG. 6A.

FIG. 7H, FIG. 71, and FIG. 7J, are possible timing diagrams output by an oscillator of FIG. 7G, as a result of receiving different configuration data.

FIG. 8 is a cross sectional diagram of a FET device with a floating gate that can be used in an NVM array.

FIG. 9 is a block diagram illustrating embodiments of how an operational component can be controlled by configuration data.

FIG. 10 is a combination electrical schematic and block diagram showing a possible implementation of the configurable circuit of FIG. 9, where an operative impedance is variable.

FIG. 11 is a flowchart illustrating a method.

### DETAILED DESCRIPTION

The present invention is now described. While it is disclosed in its preferred form, the specific embodiments of the invention as disclosed herein and illustrated in the drawings are not to be considered in a limiting sense. Rather, these embodiments are provided so that this disclosure will be thorough and complete, and will fully convey the scope of the invention to those skilled in the art. Indeed, it should be readily apparent in view of the present description that the invention may be modified in numerous ways. Among other things, the present invention may be embodied as devices, methods, software, and so on. Accordingly, the present invention may take the form of an entirely hardware embodiment, an entirely software embodiment or an embodiment combining software and hardware aspects. This description is, therefore, not to be taken in a limiting sense.

The present description is related RFID tags with one or more components whose performance depends on configuration data stored in an on-board memory, and methods. The invention is now described in more detail.

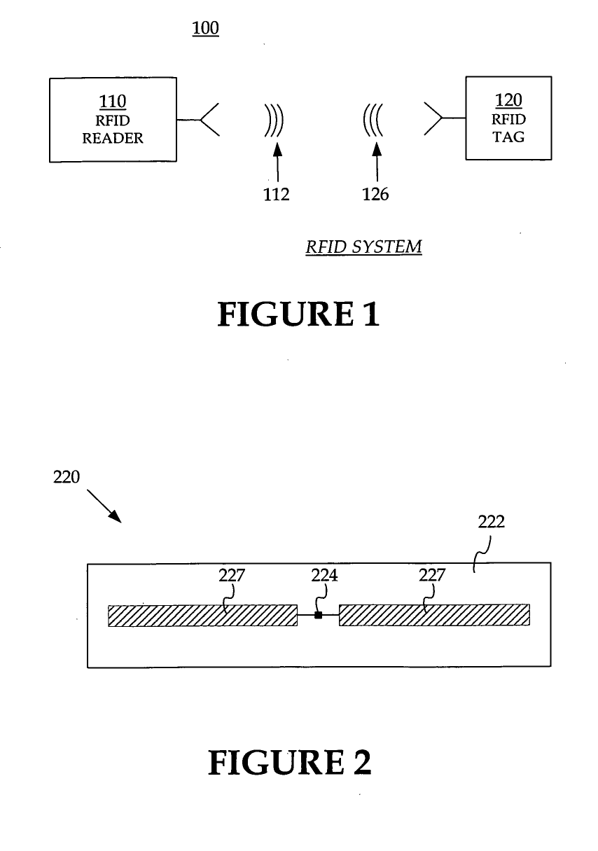

FIG. 1 is a diagram of an RFID system 100 according to the invention. An RFID reader 110 made according to the invention transmits an interrogating Radio Frequency (RF) wave 112. An RFID tag 120 made according to the invention in the vicinity of RFID reader 110 may sense interrogating RF wave 112, and generate backscatter wave 126 in response. RFID reader 110 senses and interprets backscatter wave 126.

Reader 110 and tag 120 exchange data via wave 112 and wave 126. In a session of such an exchange, each encodes and transmits data to the other, and each receives and decodes data from the other. The data is encoded into, and decoded from, RF waveforms, as will be seen in more detail below.

Encoding the data can be performed in a number of different ways. For example, protocols are devised to communicate in terms of symbols, also called RFID symbols. A symbol for communicating can be a preamble, a null symbol and so on. Further symbols can be implemented for exchanging binary data, such as “0” and “1”.

FIG. 2 is a diagram of a passive RFID tag 220. Tag 220 is formed on a substantially planar inlay 222, which can be made in many ways known in the art. Tag 220 also includes two antenna segments 227, which are usually flat and attached to inlay 222. Antenna segments 227 are shown here forming a dipole, but many other embodiments are possible.

Tag 220 also includes an electrical circuit, which is preferably implemented in an integrated circuit (IC) chip 224. IC chip 224 is also arranged on inlay 222, and electrically coupled to antenna segments 227. Only one method of coupling is shown, while many are possible.

In operation, a wireless signal is received by antenna segments 227, and communicated to IC chip 224. IC chip 224 both harvests power, and decides how to reply, if at all. If it is decided to reply, IC chip 224 modulates the impedance of antenna segments 227, which generates the backscatter from a wave transmitted by the reader. The impedance can be modulated by repeatedly coupling together and uncoupling antenna segments 227.

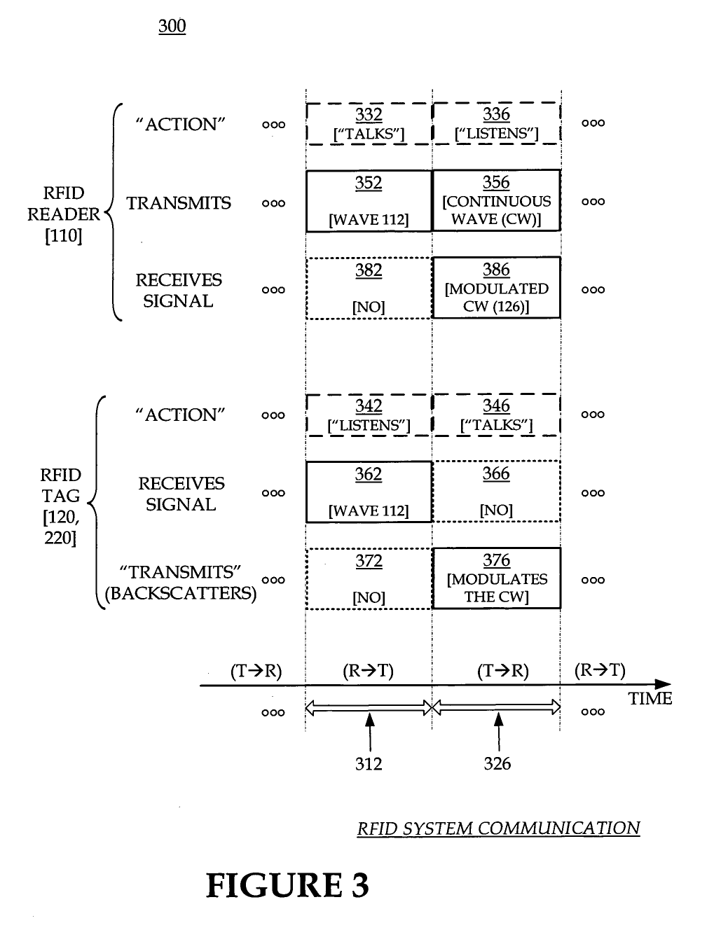

FIG. 3 is a conceptual diagram 300 for explaining the mode of communication between the components of the RFID system of FIG. 1, especially when tag 120 is implemented as passive tag 220 of FIG. 2. The explanation is made with reference to a TIME axis, and also to a human metaphor of “talking” and “listening”. The actual technical implementations for “talking” and “listening” are now described.

RFID reader 110 and RFID tag 120 talk and listen to each other by taking turns. As seen on axis TIME, when reader 110 talks to tag 120 the session is designated as “R→T”, and when tag 120 talks to reader 110 the session is designated as “T→R”. Along the TIME axis, a sample R→T session occurs during a time interval 312, and a following sample T→R session occurs during a time interval 326. Of course intervals 312, 326 can be of different durations—here the durations are shown about equal only for purposes of illustration.

According to blocks 332 and 336, RFID reader 110 talks during interval 312, and listens during interval 326. According to blocks 342 and 346, RFID tag 120 listens while reader 110 talks (during interval 312), and talks while reader 110 listens (during interval 326).

In terms of actual technical behavior, during interval 312, reader 110 talks to tag 120 as follows. According to block 352, reader 110 transmits wave 112, which was first described in FIG. 1. At the same time, according to block 362, tag 120 receives wave 112 and processes it. Meanwhile, according to block 372, tag 120 does not backscatter with its antenna, and according to block 382, reader 110 has no wave to receive from tag 120.

During interval 326, tag 120 talks to reader 110 as follows. According to block 356, reader 110 transmits towards the tag a Continuous Wave (CW), which can be thought of as a carrier signal that ideally encodes no information. As discussed before, this carrier signal serves both to be harvested by tag 120 for its own internal power needs, and also to generate a wave that tag 120 can backscatter. Indeed, at the same time, according to block 366, tag 120 does not receive a signal for processing. Instead, according to block 376, tag 120 modulates the CW emitted according to block 356, so as to generate backscatter wave 126. Concurrently, according to block 386, reader 110 receives backscatter wave 126 and processes it.

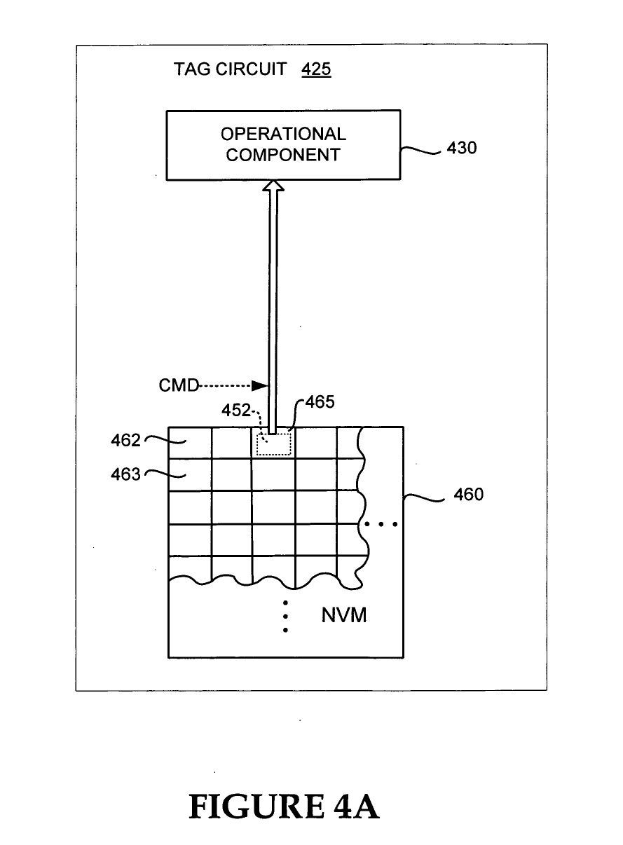

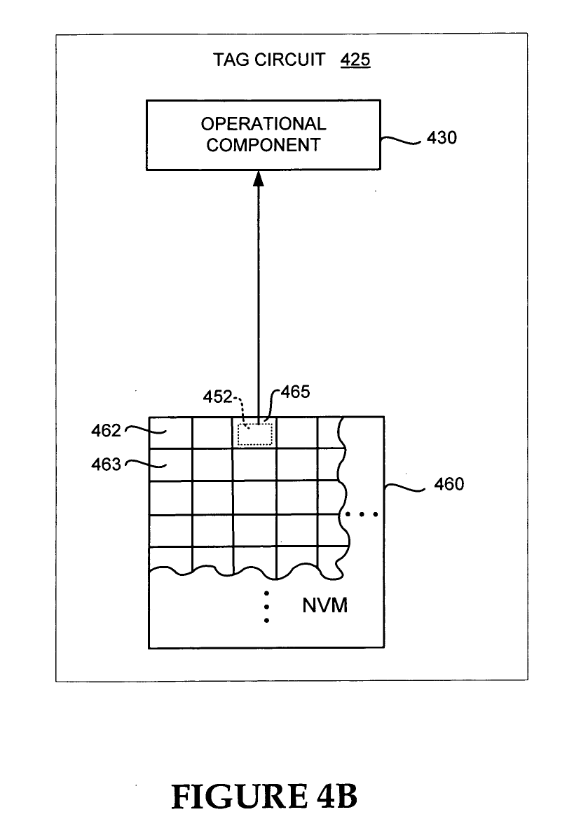

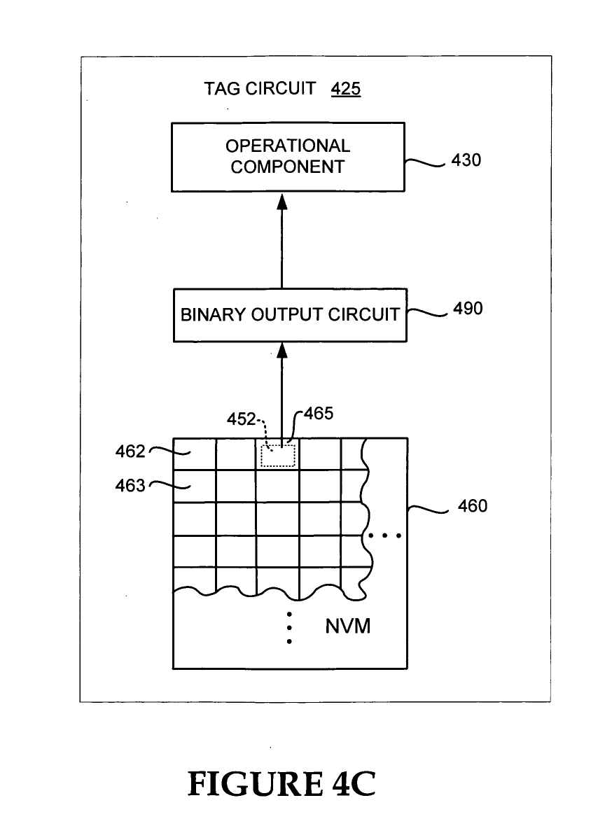

FIG. 4A is a block diagram of salient components of an RFID tag circuit according to embodiments of the invention. A tag circuit 425 includes a non-volatile memory (NVM) memory array 460, which has NVM cells 462, 463, . . . 465, . . . . Cells 462, 463, . . . , 465, . . . are addressable in terms of a row, a column, or both. If both, NVM cells 462, 463, . . . 465, . . . are arranged rectangularly. A generated address is applied to a row selection circuit, a column selection circuit, or both, and so on as is known with memories. Cells 462, 463, . . . , 465, . . . store data, and maintain it even when tag circuit 425 loses power.

Tag circuit 425 also includes an operational component 430. As will be seen later in this description, operational component 430 is intended to be any one or more of a large possible number of components of circuit 425, including (NVM) memory array 460 itself, or even a controller that is described later.

Operational component 430 operates based on configuration data. A number of ways for accomplishing this are described later in this document. A distinction should be kept in mind, however, that the configuration data based on which operational component 430 operates is different from data that might be stored in the tag regarding its use, such as a serial number.

Array 460 can store configuration data 452, which is the configuration data for operational component 430. Configuration data 452 encodes at least one value, or a series of values, for one or more operational components such as operational component 430. In some embodiments, a value for configuration data 452 is encoded in an amount of charge stored in a device. In another embodiment, configuration data 452 is at least one logical bit, such as a 1 or a zero, stored in a cell 465. Of course, configuration data 452 may need more than one cells, and so on.

Array 460 may or may not be able to store other data for the tag. If not, then another NVM memory array may be provided. The other array has cells that are addressable in terms of a row and a column, and so on.

Configuration data 452 may be input in operational component 430 via any number of paths. Two examples are described below. In these examples, as configuration data 452 is moved, it may change nature, or what it encodes, as will be seen.

FIG. 4B shows again tag circuit 425 of FIG. 4A. In the embodiment of FIG. 4B, configuration data 452 is input in operational component 430 directly from cell 465.

FIG. 4C shows again tag circuit 425 of FIG. 4A. In the embodiment of FIG. 4C, configuration data 452 is input in operational component 430 indirectly. Before being input in operational component 430, configuration data 452 may be routed through any suitable component. In the particular example of FIG. 4C, configuration data 452 is first input from cell 465 in a binary output circuit 490. Then, from circuit 470, configuration data 452 is input in operational component 430.

Binary output circuit 490 may be implemented in any number of ways. In some embodiments, it is a logic circuit, such as a gate. In other embodiments, includes a buffer, a latch, and so on.

Returning to FIG. 4A, configuration data 452 may become available to operational component 430 in any number of ways. In some embodiments, configuration data 452 is always available to operational component 430, such as by the requisite connections.

In other embodiments, operational component 430 inputs configuration data 452 responsive to a command signal CMD. Any one type of a command signal may be used, such as a reset signal, and so on. In addition, a command signal may be generated during testing, whether a tag is tested individually, or while still on a wafer, as is described below.

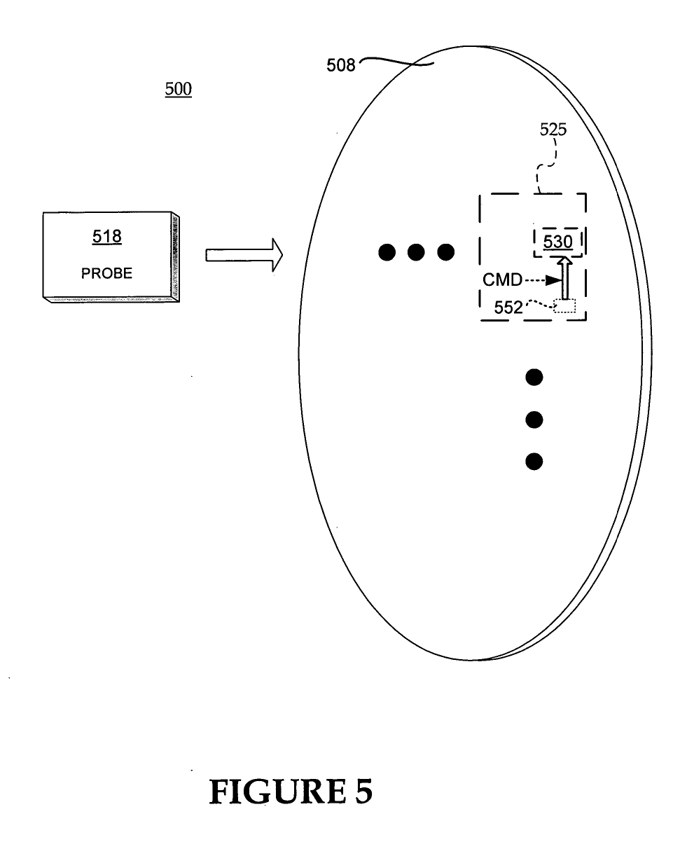

FIG. 5 is a perspective diagram of a wafer 508 being tested and/or initialized by a probe 518. Wafer 508 includes many RFID tag circuits, such as circuit 525, which are tested by probe 518. After testing and/or initializing, wafer 508 is to be cut such that a standalone small chip would include circuit 525. The exact configuration for testing and cutting is implemented any way known in the art. Alternately, the wafer may be cut into segments, and then one or more circuits per segment may be tested. Then the segment may be cut into individual chips.

Circuit 525 includes an operational component 530, similar to operational component 430 described above. Operational component 530 is adapted to input configuration data 552 during testing and/or initializing responsive to a command signal CMD, similarly to what was described above. In addition, command signal CMD in the embodiment of FIG. 5 may be generated by an action of probe 518. For example, probe 518 may apply the proper signals to circuit 525 to activate certain components, and so on. Or probe 518 may furnish configuration data 552, and so on.

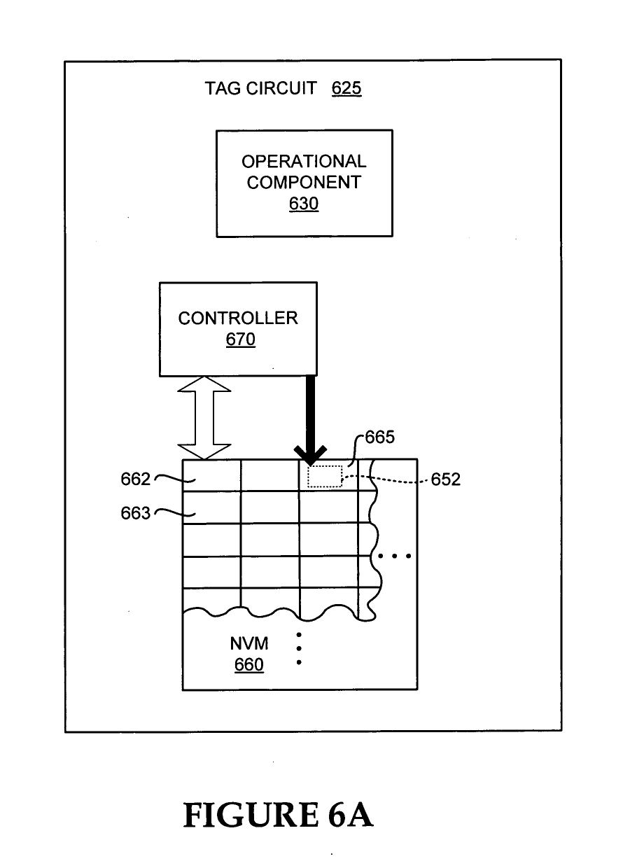

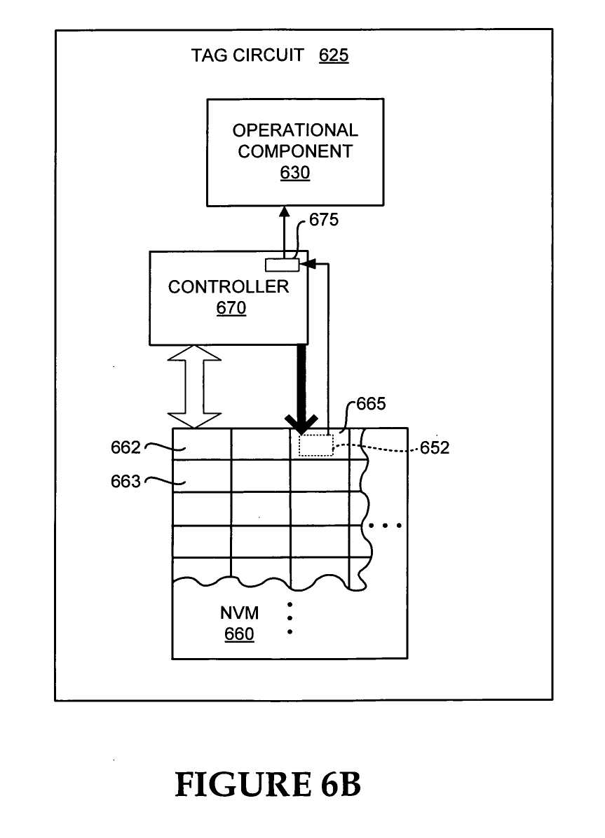

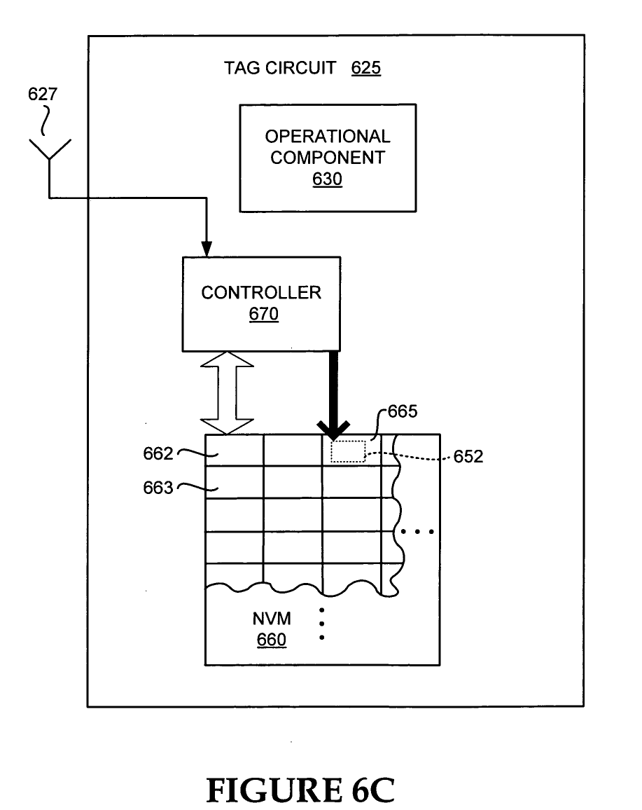

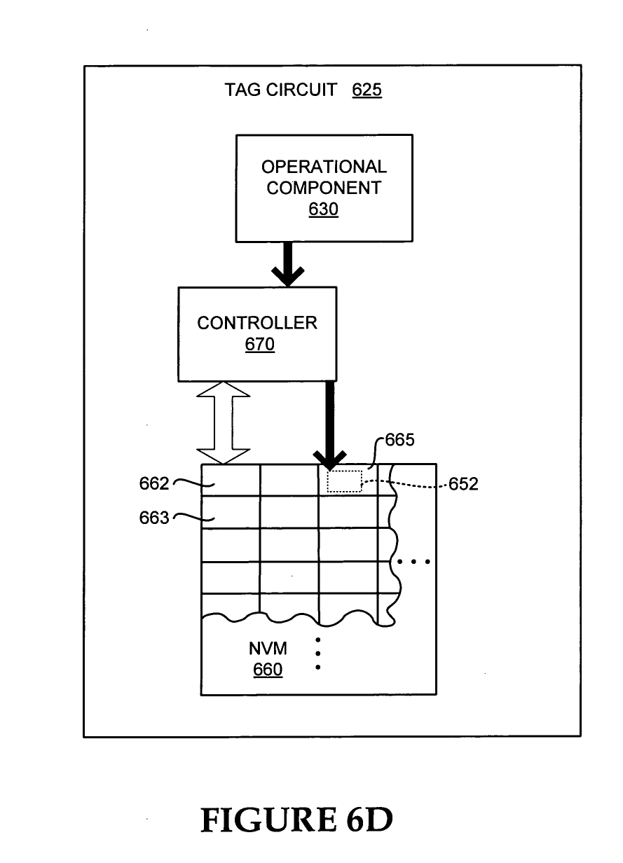

FIG. 6A is a block diagram of salient components of an RFID tag circuit according to another embodiment of the invention. A tag circuit 625 includes an operational component 630, similar to operational component 430. Operational component 630 operates based on configuration data.

Tag circuit 625 also includes a NVM memory array 660, similar to array 460. Three NVM cells 662, 663, 665 of array 660 are shown. At least one cell 665 stores configuration data 652, which is the configuration data for operational component 630. Of course, configuration data 652 may need more than one cells, and so on.

Tag circuit 625 moreover includes a controller 670. Controller 670 is adapted to program configuration data 652 in cell 665. In addition, controller 670 may cooperate with other components, such as operational component 630, NVM memory array 660, and so on.

Configuration data 652 may be input in operational component 630 via any number of paths. For example, configuration data 652 may be input in operational component 630 directly from cell 665, similarly to what was described above with reference to FIG. 4B. Or configuration data 652 may be first routed via another element, similarly to what was described above with reference to FIG. 4C.

In one more example, FIG. 6B shows again tag circuit 625 of FIG. 6A. In the embodiment of FIG. 6B, configuration data 652 is input in operational component 630 indirectly. Before being input in operational component 630, configuration data 652 is routed through any suitable component. In the particular example of FIG. 6B, configuration data 652 is first input in controller 670, such as in a register 675. Then, from controller 670, configuration data 652 is input in operational component 630.

In a number of embodiments, controller 670 is adapted to determine what configuration data 652 to program in cell 665. Two examples are described below.

FIG. 6C shows again tag circuit 625 of FIG. 6A. In addition, circuit 625 includes an antenna 627, which can be the antenna of the RFID tag. Antenna 627 is adapted to receive a wireless signal, and controller 670 determines configuration data 652 from the received wireless signal.

FIG. 6D shows again tag circuit 625 of FIG. 6A. In addition, controller 670 is adapted to sense a performance of operational component 630. Controller 670 then determines configuration data 652 so as to adjust the performance. The performance may be optimized, if needed. In some instances, adjusting can be to diminish the performance if, for example, more privacy is required.

This feature of determining what configuration data 652 to program may be invoked spontaneously, autonomously, in response to a received command, and so on. Adjusting may be desired if the performance has changed, for example either due to the passage of time, or due to changed environmental conditions, and so on. Adjusting may also take place while manufacturing or testing a tag, or preparing it for field use. For example, the processor may step through a number of values to adjust the antenna reception.

As written above, operational component 430, 530, 630 may be any one or more of any of the tag circuit components. If more than one, then a plurality of configuration data is stored. For each one of the possible operational components, one or more of their operation or performance characteristics may be controlled and/or changed by the configuration data. A number of examples are illustrated below, while manners of controlling are described later in this document.

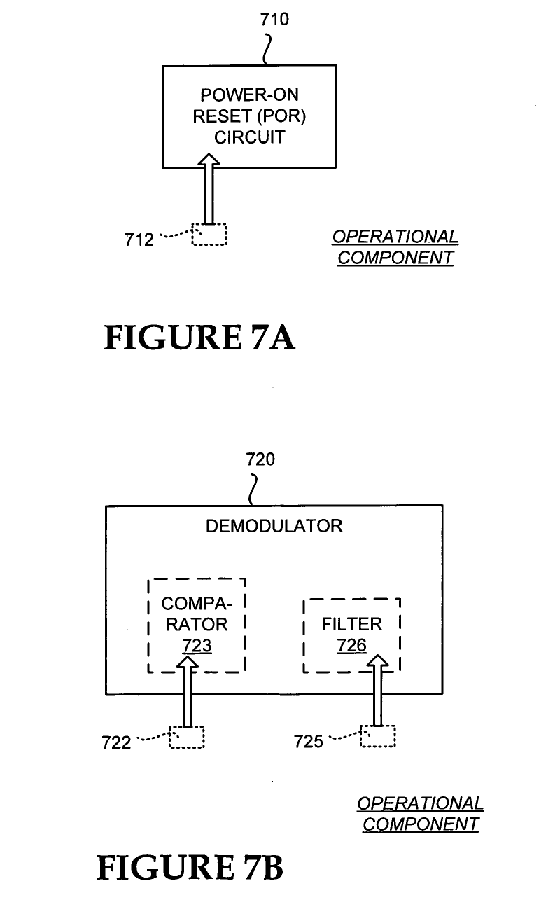

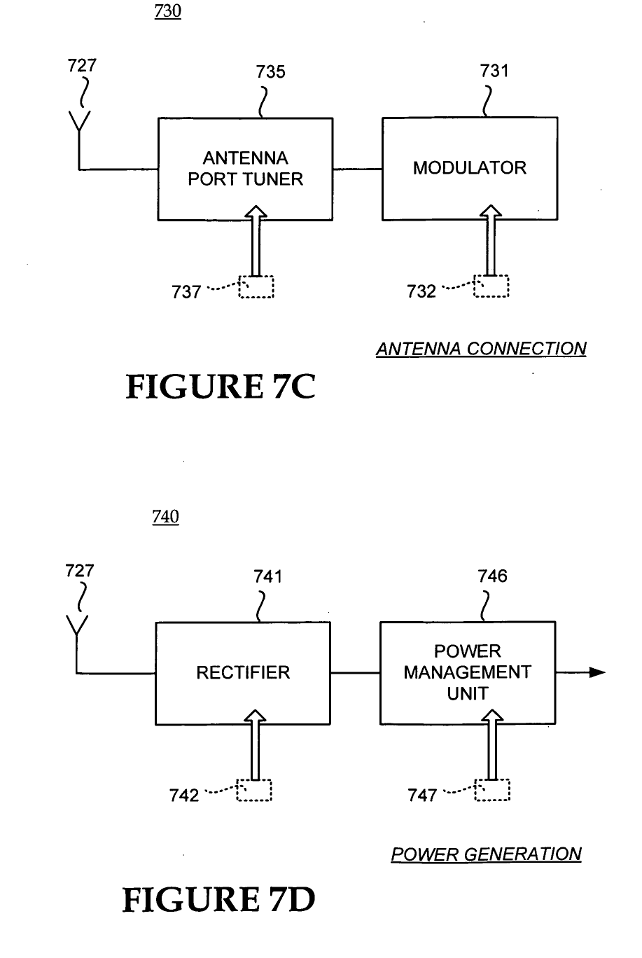

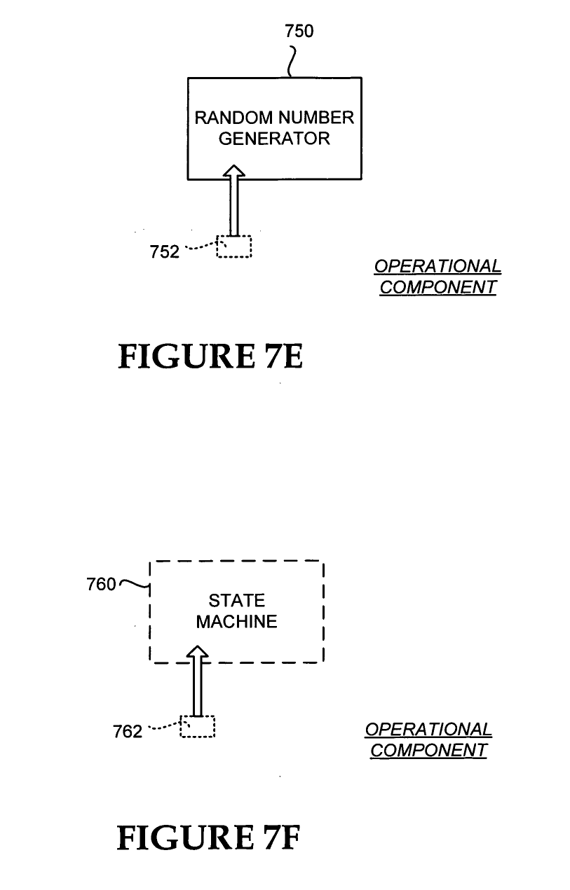

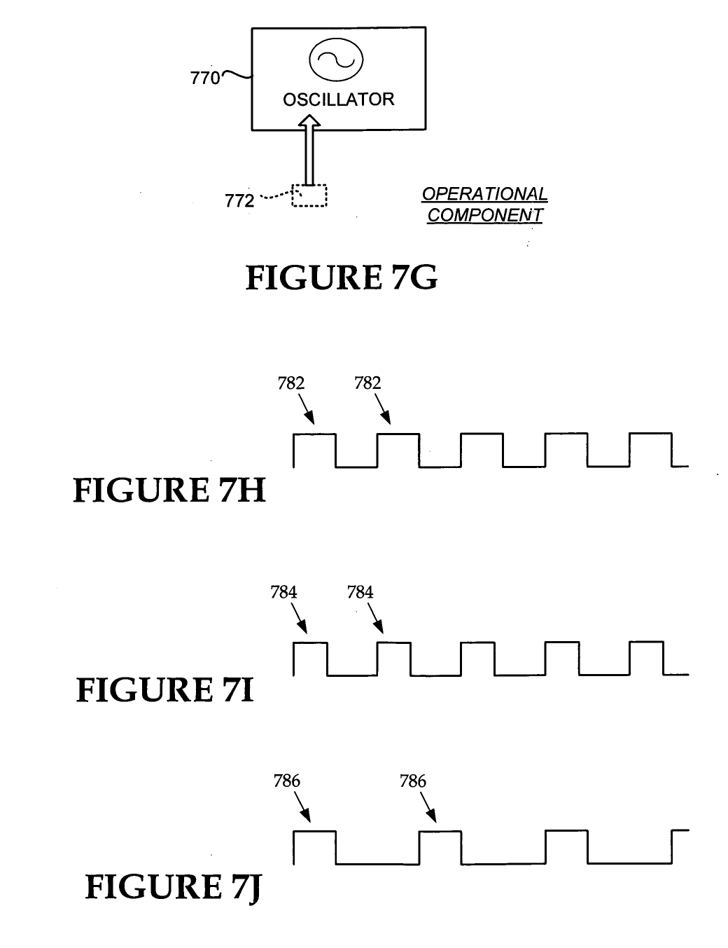

FIG. 7A is a block diagram of an embodiment of an operational component that is a power-on reset (POR) circuit 710. Configuration data 712 may control any operational parameter of POR circuit 710, such as a reset threshold.

FIG. 7B is a block diagram of an embodiment of an operational component that is a demodulator 720. Configuration data may control any number of operational components of demodulator 720. For example, configuration data 722 may control a comparator 723, configuration data 725 may control a filter 726, and so on.

FIG. 7C is a block diagram of an embodiment of an antenna connection 730. Connection 730 as shown is used for outputting data by backscattering.

Connection 730 may involve an antenna 727, an operational component that is a modulator 731, and an operational component that is an antenna port tuner 735. Configuration data may control either modulator 731, or antenna port tuner 735, or both. For example, configuration data 732 may control any operational parameter of modulator 731, such as modulation depth and/or transmitted backscattered signal power. In addition, configuration data 737 may control any operational parameter of antenna port tuner 735, such as its impedance. In this case, the impedance may have adjustable reactance components, such as capacitance and inductance. And again, the distinction is repeated that modulator 731 would output via backscattering data other than configuration data 732.

FIG. 7D is a block diagram of an embodiment of a power generation circuit 740. Circuit 740 as shown is used for generating electrical power for the tag.

Circuit 740 may involve antenna 727, an operational component that is a rectifier 741, and an operational component that is a power management unit (PMU) 746. Configuration data may control either rectifier 741, or PMU 746, or both. For example, configuration data 742 may control any operational parameter of rectifier 741, and configuration data 747 may control any operational parameter of PMU 746.

FIG. 7E is a block diagram of an embodiment of an operational component that is a random number generator (RNG) 750. Configuration data 752 may control any operational parameter of RNG 750, such as to supply an encoded seed for generating random numbers.

FIG. 7F is a block diagram of an embodiment of an operational component that is a state machine 760. Configuration data 762 may control any operational parameter of state machine 760.

State machine 760 may be a standalone state machine for the whole tag. Or it may be a state machine for an operational component, such as those described in this document. For example, it may be a state machine of NVM memory array 660. Or it may be a state machine of controller 670.

In some embodiments, an operational component is to receive one of a number of available clocks signals. In these embodiments, a state machine for the operational component includes a multiplexer. The multiplexer may receive configuration data in the form of one or more bits. The received bits control which one of the available clocks signals is received through the multiplexer. In the event where there are only two clock signals, only a single bit is needed.

In some embodiments, state machine 760 deals with whether a tag has the feature of backscattering continuously, and how to address a reader command to do so. Backscattering continuously would be performed in a testing mode, for measuring the backscattered power. During that mode, contrary to what is shown in FIG. 3, the tag would be backscattering even during the R→T sessions 312.

In some embodiments, configuration data 762 can encode one of two values. The first value indicates that a backscatter continuously feature is available, while the second value indicates that it is not. Various combinations, features, or alternative approaches are possible.

In a number of embodiments, configuration data 762 causes the tag to ignore a command by a reader to backscatter continuously. That embodiment is particularly useful where the tag is not capable of backscattering continuously, or has been otherwise programmed not to.

In other embodiments, configuration data 762 causes the tag to be in a state of backscattering continuously. That embodiment would be useful in a situation where performing such testing is desired, or in jurisdictions where such testing is required. In one of these embodiments, configuration data 762 is enabled when a test command is received. In another one of these embodiments, configuration data 762 is enabled at power up, for example in response to a POR signal.

In yet other embodiments, configuration data 762 causes the tag to react to a command by a reader to backscatter continuously. Reacting can be by issuing a response, such as non-compliance or intended compliance.

FIG. 7G is a block diagram of an embodiment of an operational component that is an oscillator 770. Oscillator 770 may also be known as a clock signal generator, or may be a part of a clock signal generator. Configuration data 772 may control any operational parameter of oscillator 770, or a broader clock signal generator.

FIG. 7H, FIG. 7I, and FIG. 7J, are possible timing diagrams output by oscillator 770, or an associated clock signal generator, as a result of inputting different configuration data 772. These timing diagrams are given so that the impact of different configuration data 772 will be better appreciated.

FIG. 7H shows a first possible output of oscillator 770, which includes successive pulses 782.

FIG. 7I shows a second possible output of oscillator 770, which includes successive pulses 784. Pulses 784 have the same frequency, but a different duty cycle than pulses 782 of FIG. 7H.

FIG. 7J shows a third possible output of oscillator 770, which includes successive pulses 786. Pulses 786 have a different frequency than pulses 782 of FIG. 7H.

Differences in generated pulses such as the above are attained by inputting different configuration data 772 in oscillator 770. Such can be inputted in different ways, for example adjusting an impedance, directly or indirectly, and so on.

In some embodiments, a Voltage Controlled Oscillator (VCO) is used, where adjusting a voltage adjusts a frequency. The VCO can be controlled by voltage output from a Digital to Analog Converter (DAC), which in turn can receive configuration data in the form of a binary input (one or more bits).

In other embodiments, a Current Controlled Oscillator (CCO) is used, preferably as controlled by a current-output Digital to Analog Converter (DAC). Again the DAC can receive configuration data in the form of a binary input. A “current-starved ring oscillator” is one common, well-known example of a current-controlled oscillator.

In further embodiments, oscillator 770 is implemented by at least one or more delay cells, whose delay can be affected by configuration data, such as input bits. A versatile embodiment includes at least two delay cells. If the bits affect the delay cells in the same direction, the frequency is adjusted. If the bits affect the delay cells in opposite directions, the frequency may stay the same, but the duty cycle is adjusted.

A number of embodiments are possible for the cells of NVM arrays of the invention. For example, such cells can use a mechanism for nonvolatile storage of information that is magnetoresistive, ferroelectric, phase-change, dielectric, and so on.

One such mechanism is now described in more detail, which uses a transistor that stores charge in a floating gate, such as a CMOS transistor. The transistor can be nFET, pFET, FinFET, multi-gate FET, and so on. In addition, more implementation details for these items can also be found in the incorporated three co-pending patent applications, mentioned at the beginning of this document.

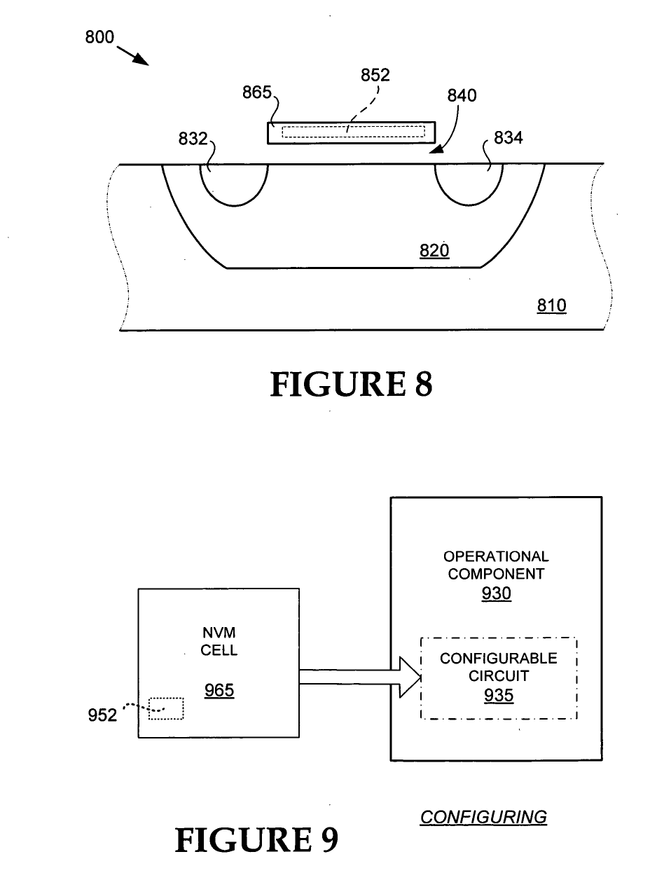

FIG. 8 is a cross sectional diagram of a FET transistor device 800, such as a CMOS transistor. Transistor 800 can be of either the pnp polarity, or the npn polarity. Where multiple transistors are called for, either or both polarities may be used. The description of the three incorporated applications proceeds mostly in terms of one of the two polarities, but these are presented as an illustration, and not as a limitation. Indeed, one can interchange the n and the p polarities recited in the three incorporated applications to practice the present description.

Transistor device 800 is formed in a semiconductor substrate 810. A doped well 820 is formed in semiconductor substrate 810. A heavily doped source region 832 and a heavily doped drain region 834 are formed in well 820, defining a channel between them. A dielectric insulating layer (not shown) is formed in an area 840 over the channel. A gate 865 is formed over area 840, which hosts an electrical charge 852. Gate 865 is called a floating gate, because it has a voltage that changes (“floats”), depending on the changing amounts of the electrical charge 852.

In the embodiment of FIG. 8, configuration data is encoded in terms of the amount of charge 852 be stored on floating gate 865.

For transistor 800, programming a different value for the configuration data can be performed by changing the amount of charge 852 on floating gate 865. The charge may be changed by any number of ways, accomplished by building suitable structures and operating suitable circuits for transistor 800. These ways include Fowler-Nordheim tunneling, bidirectional Fowler-Nordheim tunneling, hot-electron injection, direct tunneling, hot-hole injection, ultraviolet radiation exposure, and so on.

FIG. 9 is a block diagram illustrating embodiments of how an operational component can be controlled by configuration data. In FIG. 9, a NVM cell 965 stores configuration data 952 for an operational component 930.

Operational component 930 may be any operational component in an RFID tag circuit, such as one of the components described above. In addition, operational component 930 is considered to include a configurable circuit 935 that is responsive to configuration data 952.

In some embodiments, configurable circuit 935 is adapted to exhibit a characteristic that varies according to different values encoded in configuration data 952. In a basic embodiment, the configurable circuit includes an ON/OFF switch. In one embodiment, configurable circuit 935 includes a state machine, as also per the above.

In some embodiments, the variable characteristic is an operative impedance. As is well known, impedance includes any combination of electrical resistance and reactance. The reactance includes any combination of inductance and capacitance. In the above mentioned example of an ON/OFF switch, resistance might simply take two values, one very small (ON) and one very large (OFF).

Various examples are now described of varying impedance according to configuration data. One such example is described below.

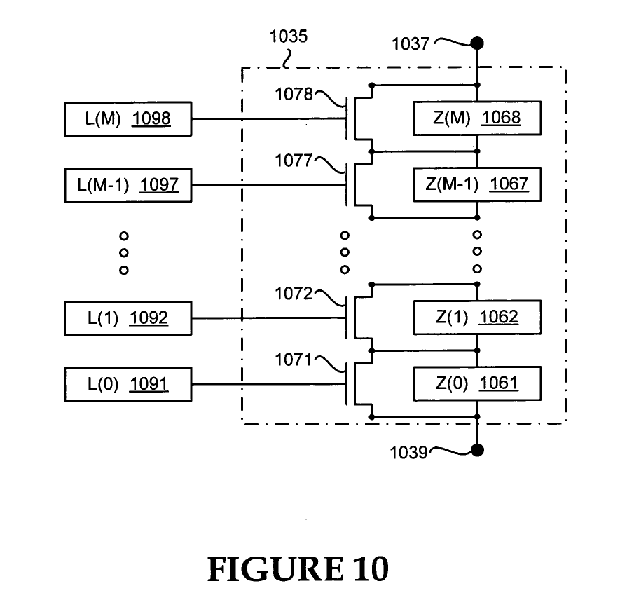

FIG. 10 is a combination electrical schematic and block diagram, showing a possible implementation of a configurable circuit 1035, having terminals 1037 and 1039. Between terminals 1037 and 1039 there are M+1 impedance blocks or components Z(0) 1061, Z(1) 1062, . . . , Z(M−1) 1067, and Z(M) 1068, where M is an integer.

While the embodiment of FIG. 10 shows impedance blocks Z(0) 1061, Z(1) 1062, . . . , Z(M−1) 1067, and Z(M) 1068 in series, other implementations are also possible. For example, parallel combinations are possible, as well as series parallel combinations.

FIG. 10 also shows switches 1071, 1072, . . . , 1077, and 1078, which may be implemented by transistors, such as FET transistors and so on. Switches 1071, 1072, . . . , 1077, and 1078 can individually switch ON and OFF, so that they can allow respective individual impedance blocks Z(0) 1061, Z(1) 1062, . . . , Z(M−1) 1067, and Z(M) 1068 to be part of the total impedance between terminals 1037 and 1039, or be bypassed. This way, the operative impedance between terminals 1037 and 1039 is discretely variable, each time determined by accounting for the individual impedances of those of impedance blocks Z(0) 1061, Z(1) 1062, . . . , Z(M−1) 1067, and Z(M) 1068 that are not bypassed. In some of these embodiments, it is advantageous to choose the impedance values of blocks Z(0) 1061, Z(1) 1062, . . . , Z(M−1) 1067, and Z(M) 1068 to be multiples of each other, so that a range can be covered.

Switches 1071, 1072, . . . , 1077, and 1078 can individually switch ON and OFF depending on the digital binary output of elements L(0) 1091, L(1) 1092, . . . , L(M−1) 1097, and L(M) 1098. These elements L(0) 1091, L(1) 1092, . . . , L(M−1) 1097, and L(M) 1098 can be a memory cell such as memory cell 465, a binary output circuit such as circuit 490, and so on. Additionally, elements L(0) 1091, L(1) 1092, . . . , L(M−1) 1097, and L(M) 1098 are controlled by configuration data (not depicted), directly or indirectly, as described above. It will be appreciated that such an arrangement does not use a single value of configuration data, but multiple values. And these values can be considered to form a single number, such as a multi-bit binary number.

Returning briefly to FIG. 7G, oscillator 770 may be implemented by an LC (inductor-capacitor), RC (resistor capacitor), ring oscillator, and so on. A frequency and or/duty cycle can be adjusted by adjusting an operative impedance, for example a resistance, a capacitance, a product of resistance and capacitance, and so on.

For another example, in one embodiment, the oscillator frequency can depend on the product of a capacitance (that is not changed) and the resistance of a transistor in the triode region of operation. The bias point of the transistor in triode operation depends on a bias circuit, which in turn depends on a resistor. Switches short out parts of the resistor in the bias circuit, which then affects the bias point of the triode transistor, and in turn changes the frequency. Depending on where boundaries are considered, such a complex implementation looks either like a resistor-controlled oscillator, or a resistor-controlled current DAC that drives a current-controlled oscillator, or a resistor-controlled voltage DAC that drives a VCO, and so on.

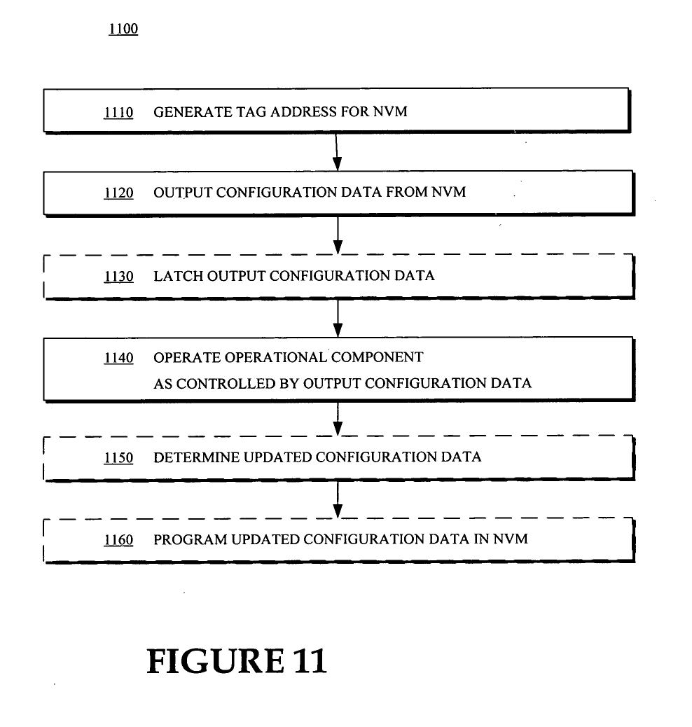

FIG. 11 is flowchart 1100 illustrating a method. The method of flowchart 1100 may also be practiced by different tags circuits, including but not limited to circuits 425, 525, 625.

According to a box 1110, an address is generated for an NVM array of a tag. The address is in terms of a row, column, or both, and points to one or more cells. The address is applied to a row selection circuit, a column selection circuit, or both, and so on as is known with memories.

At next block 1120, stored configuration data is output from the pointed cell or cells. At optional next block 1130, the configuration data is latched, such as in a binary output circuit. As per the above, the binary output circuit can be a latch, buffer or gate, and so on.

At next block 1140, an operational component of the tag circuit is operated, as controlled by the output configuration data. If the data has been latched, it is received from the latch. The operational component can be operated as controlled by an exhibited characteristic of a configurable circuit of the component. The characteristic is variable and dependent on the input configuration data, as per the above.

At optional next block 1150, updated configuration data is determined for storing in the cell or cells, or other cells. Determining takes place as described above.

At optional next block 1160, configuration data is stored in the cells, such as updated configuration data.

Numerous details have been set forth in this description, which is to be taken as a whole, to provide a more thorough understanding of the invention. In other instances, well-known features have not been described in detail, so as to not obscure unnecessarily the invention.

The invention includes combinations and subcombinations of the various elements, features, functions and/or properties disclosed herein. The following claims define certain combinations and subcombinations, which are regarded as novel and non-obvious. Additional claims for other combinations and subcombinations of features, functions, elements and/or properties may be presented in this or a related document.

What is claimed is:

1. An RFID tag circuit comprising:
a non-volatile memory (NVM) memory array having a plurality of NVM storage cells that are addressable in terms of at least one of a row and a column, at least a first one of the cells being adapted to store configuration data in a way that survives loss of power; and
an operational component adapted to operate based on the configuration data.

2. The circuit of claim 1, further comprising:
another NVM memory array having cells that are addressable in terms of at least one of a row and a column, at least some of the cells of the other array being adapted to store data in a way that survives loss of power.

3. The circuit of claim 1, wherein
the configuration data is at least one logical bit.

4. The circuit of claim 1, wherein
a value for the configuration data is encoded in an amount of charge stored in a device.

5. The circuit of claim 1, wherein
the configuration data is input in the operational component directly from the first cell.

6. The circuit of claim 1, wherein
the configuration data is first input in a binary output circuit from the first cell, and then it is input in the operational component from the binary output circuit.

7. The circuit of claim 6, wherein
the binary output circuit is a logic circuit.

8. The circuit of claim 6, wherein
the binary output circuit includes one of a buffer and a latch.

9. The circuit of claim 1, wherein
the operational component inputs the configuration data responsive to a command signal.

10. The circuit of claim 9, wherein
the command signal is a reset signal.

11. The circuit of claim 9, wherein
the command signal is received during testing.

12. The circuit of claim 11, wherein
the command signal is received while the circuit is formed in a wafer segment comprising a plurality of additional RFID tag circuits.

13. The circuit of claim 11, wherein
testing is performed by a probe, and
the command signal is generated by an action of the probe.

14. The circuit of claim 1, wherein
the operational component is a power-on reset circuit.

15. The circuit of claim 1, wherein
the operational component is a demodulator.

16. The circuit of claim 1, wherein
the operational component is a modulator.

17. The circuit of claim 1, wherein
the operational component is an antenna port tuner.

18. The circuit of claim 1, wherein
the operational component is a rectifier.

19. The circuit of claim 1, wherein
the operational component is a power management unit.

20. The circuit of claim 1, wherein
the operational component is a random number generator.

21. The circuit of claim 1, wherein
the operational component is an oscillator.

22. The circuit of claim 1, wherein
the operational component is a state machine of the tag.

23. The circuit of claim 1, wherein
the operational component is a state machine of the NVM memory array.

24. The circuit of claim 1, wherein
the operational component is a state machine that includes a multiplexer.

25. The circuit of claim 1, further comprising:
a controller adapted to program the configuration data in the first cell.

26. The circuit of claim 25, wherein
the configuration data is input in the operational component directly from the first cell.

27. The circuit of claim 25, wherein
the configuration data is first input in the controller from the first cell, and then it is input in the operational component from the controller.

28. The circuit of claim 25, wherein
the configuration data is first input in a binary output circuit from the first cell, and then it is input in the operational component from the binary output circuit.

29. The circuit of claim 28, wherein
the binary output circuit is a logic circuit.

30. The circuit of claim 28, wherein
the binary output circuit includes one of a buffer and a latch.

31. The circuit of claim 25, wherein
the controller is adapted to determine the configuration data to program in the first cell.

32. The circuit of claim 31, further comprising:
an antenna for receiving a wireless signal, and
wherein determining is performed from the received wireless signal.

33. The circuit of claim 31, wherein
the controller is adapted to sense a performance of the operational component, and
wherein determining is performed so as to adjust the performance.

34. The circuit of claim 25, wherein
the operational component is a power-on reset circuit.

35. The circuit of claim 25, wherein
the operational component is a demodulator.

36. The circuit of claim 25, wherein
the operational component is a modulator.

37. The circuit of claim 25, wherein
the operational component is an antenna port tuner.

38. The circuit of claim 25, wherein
the operational component is a rectifier.

39. The circuit of claim 25, wherein
the operational component is a power management unit.

40. The circuit of claim 25, wherein
the operational component is a random number generator.

41. The circuit of claim 25, wherein
the operational component is an oscillator.

42. The circuit of claim 25, wherein
the operational component is a state machine.

43. The circuit of claim 42, wherein
the operational component is a state machine of the NVM memory array.

44. The circuit of claim 42, wherein
the operational component is a state machine of the controller.

45. The circuit of claim 42, wherein
the state machine includes a multiplexer.

46. The circuit of claim 42, wherein
the configuration data can encode one of two values, a first one of the two values indicating that a backscatter continuously feature is available, and a second one of the two values indicating that it is not.

47. The circuit of claim 42, wherein
the configuration data causes the tag to ignore a command by a reader to backscatter continuously.

48. The circuit of claim 42, wherein
the configuration data causes the tag to react to a command by a reader to backscatter continuously.

49. The circuit of claim 42, wherein
the configuration data causes the tag to be in a state of backscattering continuously.

50. The circuit of claim 1, wherein
the first cell uses a mechanism for nonvolatile storage of information selected from the group consisting of magnetoresistive, ferroelectric, phase-change, and dielectric.

51. The circuit of claim 1, wherein
the first cell includes a floating gate of a floating-gate transistor, and
the configuration data is stored in terms of a variable amount of charge on the floating gate.

52. The circuit of claim 51, wherein
the floating-gate transistor is a transistor selected from the group consisting of:
nFET, pFET, FinFET, and multi-gate FET.

53. The circuit of claim 51, wherein
the amount of charge may be changed using Fowler-Nordheim tunneling.

54. The circuit of claim 51, wherein
the amount of charge may be changed using bidirectional Fowler-Nordheim tunneling.

55. The circuit of claim 51, wherein
the amount of charge may be changed using hot-electron injection.

56. The circuit of claim 51, wherein
the amount of charge may be changed using direct tunneling.

57. The circuit of claim 51, wherein
the amount of charge may be changed using hot-hole injection.

58. The circuit of claim 51, wherein
the amount of charge may be changed using ultraviolet radiation exposure.

59. The circuit of claim 1, wherein
the operational component includes a configurable circuit adapted to exhibit a characteristic that varies according to the configuration data.

60. The circuit of claim 59, wherein
the configurable circuit includes an ON/OFF switch.

61. The circuit of claim 59, wherein
the configurable circuit includes a state machine.

62. The circuit of claim 59, wherein
the variable characteristic is an operative impedance.

63. The circuit of claim 62, wherein
the operational component includes an impedance component, and
the configurable circuit includes a switch for controlling whether the impedance component will be part of the operative impedance.

64. A device comprising:
means for generating an address for a tag non-volatile memory (NVM) array in terms of at least one of a row and a column;
means for outputting, in response to the address, configuration data stored in the array in a way that survives loss of power; and
means for operating a tag operational component as controlled by the output configuration data.

65. The device of claim 64, further comprising:
means for latching the configuration data.

66. The device of claim 64, wherein
the address is generated responsive to a command signal.

67. The device of claim 64, further comprising:
means for programming the configuration data in the array.

68. The device of claim 67, further comprising:
means for determining the configuration data to program in the array.

69. A method for an RFID tag circuit comprising:
generating an address for a tag non-volatile memory (NVM) array in terms of at least one of a row and a column;
outputting, in response to the address, configuration data stored in the array in a way that survives loss of power; and
operating a tag operational component as controlled by the output configuration data.

70. The method of claim 69, wherein
the operational component includes a configurable circuit,
the component is operated as controlled by an exhibited characteristic of the configurable circuit, and
the characteristic is variable and dependent on the configuration data.

71. The method of claim 69, wherein
the operational component is one of a power-on reset circuit, a demodulator, a modulator, an antenna port tuner, a rectifier, a power management unit, a random number generator, an oscillator, and a state machine.

72. The method of claim 69, wherein
the configuration data causes the tag to ignore a command by a reader to backscatter continuously.

73. The method of claim 69, wherein
the configuration data causes the tag to react to a command by a reader to backscatter continuously.

74. The method of claim 69, wherein
the configuration data causes the tag to be in a state of backscattering continuously.

75. The method of claim 74, further comprising:
measuring a backscattered power of the tag while it is continuously backscattering.

76. The method of claim 69, wherein
the configuration data is input in a binary output circuit, and
the tag operational component receives an output of the binary output circuit.

77. The method of claim 69, further comprising:
latching the configuration data.

78. The method of claim 69, further comprising:
cutting a wafer segment into a chip that includes the circuit.

79. The method of claim 69, wherein
the address is generated responsive to a command signal.

80. The method of claim 79, wherein
the command signal is a reset signal.

81. The method of claim 79, wherein
the command signal is generated responsive to a test probe.

82. The method of claim 69, further comprising:
programming the configuration data in the array.

83. The method of claim 82, further comprising:
determining the configuration data to program in the array.

84. The method of claim 83, further comprising:
receiving a wireless signal, and
wherein determining is performed from the received wireless signal.

85. The method of claim 83, further comprising:
receiving a signal from a testing device, and
wherein determining is performed from the received signal.

86. The method of claim 83, further comprising:
sensing a performance of the operational component, and
wherein determining is performed so as to adjust the performance.
